(19) United States
(12) Patent Application Publication
(10) Pub. No.: US 2025/0212700 A1
(43) Pub. Date: Jun. 26, 2025

(54) QUANTUM DEVICE WITH SUPERIMPOSED QUBITS AND LATERALLY CONTROLLED

(71) Applicant: COMMISSARIAT A L'ENERGIE ATOMIQUE ET AUX ENERGIES ALTERNATIVES, Paris (FR)

(72) Inventor: Heimanu NIEBOJEWSKI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/990,750

(22) Filed: Dec. 20, 2024

(30) Foreign Application Priority Data
Dec. 22, 2023 (FR) FR2315157

(51) Int. Cl. H10N 60/10; B82Y 10/00; G06N 10/40; H10N 60/01

(52) U.S. Cl. CPC H10N 60/128; G06N 10/40; H10N 60/01; H10N 60/11; B82Y 10/00

(57) ABSTRACT

A quantum electronic device including a first set of semiconductor regions comprising a first lower semiconductor region and a first upper semiconductor region superimposed on, and separated from, the first lower semiconductor region via a first dielectric separation zone, a second set of semiconductor regions comprising a second lower semiconductor region and a second upper semiconductor region superimposed on, and separated from, the first lower semiconductor region via a second dielectric separation zone. The first set of semiconductor regions is disposed opposite the second set of semiconductor regions, and at least one dielectric region separates the first set of semiconductor regions from the second set of semiconductor regions.

TECHNICAL FIELD AND PRIOR ART

The present application relates to the field of quantum devices in which at least one piece of quantum information based on a given quantum state out of at least two measurable levels is used as an information vector. This quantum state is referred to as qubit or quantum bit.

One particular type of qubit is the spin qubit when the intrinsic degree of freedom of the spin of individual electrons is used for coding the quantum information.

Qubits can be formed in a semiconductor material within nano-sized electrostatically and/or physically defined confinement structures. These confinement structures are typically called quantum dots.

A quantum dot behaves like a potential well confining one or more elementary charges (electrons or holes) in a semiconductor region.

To measure the state of a qubit, proceeding with a spin/charge conversion that makes it possible to convert the spin state of the charged particles into a charge state of the quantum dots containing said particles is known. It is then necessary to measure this charge state in order to deduce therefrom the spin state of the charged particles before conversion. For this, a means for measuring the charge state is generally disposed facing or in proximity to each quantum dot.

The reading of a qubit can for example be carried out by using another quantum dot called “reading island” or “detection island” coupled to that of the qubit intended to be read. These two elements form two potential wells separated by a potential barrier.

Devices in which the detection islands and quantum dots are disposed facing each other and in the same plane parallel to the main plane of a substrate on which the quantum dots and detection islands are formed are known.

The document by R Pillarisetty “High Volume Electrical Characterization of Semiconductor Qubits”, 2019 IEEE International Electron Devices Meeting (IEDM) provides for example a device with quantum dots formed in a first elongate semiconductor block (fin) and detection islands formed in a second elongate semiconductor block parallel to the first block.

The problem arises of creating a new quantum device that is improved in terms of integration density while preferably preserving good detection sensitivity.

### DISCLOSURE OF THE INVENTION

According to one aspect, an embodiment of the present invention relates to a quantum electronic device provided with a substrate and on this substrate:
a set of superimposed semiconductor bars comprising at least one lower semiconductor bar and at least one upper semiconductor bar, the lower semiconductor bar and the upper semiconductor bar being disposed one above the other,
a first group of superimposed gates comprising at least a first lower gate and a first upper gate superimposed on and separated from the first lower gate by an insulation zone, the first lower gate being disposed opposite, and capable of being coupled via capacitive coupling to, a first region of the lower semiconductor bar forming a first quantum dot, the first upper gate being disposed opposite, and capable of being coupled via capacitive coupling to, a first region of the upper semiconductor bar forming a second quantum dot,
a second group of superimposed gates comprising a second lower gate and a second upper gate superimposed on and separated from the second lower gate by an insulation zone, the first lower gate being disposed opposite a second region of the lower semiconductor bar opposite to the first region of the lower semiconductor bar, the second upper gate being disposed opposite a second region of the upper semiconductor bar opposite to the first region of the upper semiconductor bar, the first group and the second group of gates being arranged so that said set of semiconductor bars is disposed between the first group of superimposed gates and the second group of superimposed gates.

Such an arrangement with superimposed semiconductor bars and lateral gates allows to obtain a density of quantum dots arranged on several distinct planes in a direction orthogonal to the main plane and an improved lateral control of these quantum dots.

Advantageously, the device can further comprise:
a third group of superimposed gates juxtaposed with said first group of gates, the third group of superimposed gates comprising at least one third lower gate separated from a third upper gate superimposed on and separated from the third lower gate by an insulation zone, the third lower gate and the third upper gate being disposed opposite respectively a third lower semiconductor region of the lower semiconductor bar and a third upper semiconductor region of the upper semiconductor bar,
a fourth group of superimposed gates juxtaposed with said second group of gates, the fourth group of superimposed gates comprising a fourth lower gate and a fourth upper gate superimposed on and separated from the fourth lower gate by an insulation zone, the fourth lower gate and the fourth upper gate being disposed opposite respectively a fourth lower semiconductor region of the lower semiconductor bar and a fourth upper semiconductor region of the upper semiconductor bar.

Thus, superimposed rows of quantum dots can be advantageously implemented, each row being connected by a set of juxtaposed gates typically extending orthogonally to the semiconductor bars.

According to one possible implementation, between neighbouring or juxtaposed gates, and in particular between the first group of gates and said third group of gates:—at least one exchange electrode or exchange electrodes superimposed and separated from one another by at least one insulating separation layer can be provided. This allows to carry out an exchange of charges between quantum dots. Alternatively, between neighbouring or juxtaposed gates, and in particular between the first group of gates and said third group of gates, a zone of insulating material can be provided.

According to a specific embodiment of the device, the latter can be further provided with a doped semiconductor block forming a first charge reservoir, the doped semiconductor block being arranged at a first end of the upper semiconductor bar and of the first lower semiconductor bar. The device can advantageously comprise another doped semiconductor block, forming a second charge reservoir, the other doped semiconductor block being arranged at a second end of the upper semiconductor bar and of the lower semiconductor bar.

According to one possible implementation of the quantum device, the latter can be provided with a dielectric region arranged between the first group of superimposed gates and the second group of superimposed gates, this dielectric region encapsulating the superimposed semiconductor bars.

Preferably, the insulation zone separating the first upper gate and the first lower gate is in direct contact both with an upper face of the first lower gate and with a lower face of the first upper gate and only consists of dielectric material and the insulation zone separating the second upper gate and the second lower gate is in direct contact both with an upper face of the second lower gate and with a lower face of the second upper gate and only consists of dielectric material.

Advantageously, the dielectric region includes, in a first plane orthogonal to a main plane of the substrate and passing between the first group of gates of the set of superimposed semiconductor bars, a first dielectric portion only consisting of dielectric material, the first dielectric portion extending against and in contact with a lateral face of the first upper gate and against and in contact with a lateral face of the first lower gate, the first dielectric portion including an end located in the extension of a lower face of the first lower gate, and another end located in the extension of an upper face of the first upper gate.

The quantum device is particularly adapted to detection by reflectometry. Thus, the lower and upper gates of said second group of gates and/or of the first group are coupled or capable of being coupled to a circuit for measurement by reflectometry, said circuit being in particular configured to:
emit an RF signal to the second lower gate or to the second upper gate;
detect a variation in impedance consecutive to the reception of a signal reflected by said second semiconductor region of the lower semiconductor bar or by said second upper semiconductor region of the semiconductor bar consecutively to the emission of said RF signal.

According to a first possible implementation, the lower semiconductor bar and the upper semiconductor bar have a width W1 smaller than a predetermined width, the second lower gate and the second upper gate being configured to respectively control the chemical potential of the first quantum dot and the chemical potential of the second quantum dot. Thus, it is possible to provide a pair of gates disposed laterally on either side of a quantum dot to allow to control this dot.

Alternatively, and according to a second possible implementation, the lower semiconductor bar and the upper semiconductor bar have a width W1 greater than a predetermined width, the second lower gate and the second upper gate being configured to respectively control the chemical potential of a third quantum dot formed in said second region of the lower bar and the chemical potential of a fourth quantum dot formed in said second region of the upper bar.

According to a specific embodiment, the gates of said groups of gates extend orthogonally to said superimposed semiconductor bars and are disposed against lateral zones of the bars.

Advantageously, in a plane orthogonal to a main plane of the substrate and passing through said superimposed semiconductor bars, the device is devoid of an electrode or gate. The device does not therefore include here an electrode for controlling or reading the quantum dots or a gate above the structure containing these quantum dots in other words the set of bars.

An only lateral control of the bars in which the quantum dots are provided is advantageously carried out here.

Advantageously:
the first upper gate and the second upper gate are distinct gates electrically independent of one another so that the first upper gate and the second upper gate can be set to different respective potentials, and/or
the first lower gate and the second lower gate are distinct gates electrically independent of one another so that the first lower gate and the second lower gate can be set to different respective potentials.

According to another aspect, the present invention relates to a method for manufacturing a quantum device as defined above.

Thus, according to one possible implementation, this method can comprise steps of:
creating on said substrate a structure formed by a stack of semiconductor bars formed by an alternation of bars containing a first material and bars containing a second material, the second material being semiconductor, then
forming gate patterns on either side of and against said stack structure, then
freeing in said structure the bars containing the second material by selective removal of the bars containing the first material.

Advantageously, the freeing of the bars containing the second material leads to freeing a space between said gate pattern and around the bars containing the second material, the method further comprising: a step of filling said space using at least one dielectric material.

According to one possible implementation, the method can further comprise, before the formation of the gate patterns on either side of and against said structure, steps of:
partially etching the bars containing the second material by selective etching with respect to the first material so as to form recesses on either side of the lateral sides of said structure, then
forming dielectric plugs in said recesses.

According to a specific implementation, the method can further comprise, after formation of said structure and before the freeing in said structure of the bars containing the second material, a formation of charge reservoirs at ends of said structure, the formation of the charge reservoirs comprising:
carrying out a partial selective etching of the first material with respect to the second material in order to create hollows at said ends of said stack structure,
filling said hollows with an insulating material in order to form insulating plugs in said hollows,
carrying out an epitaxy of semiconductor material starting from exposed ends of the bars containing the second material, while the bars containing the first material are protected by the insulating plugs.

Advantageously, the gate patterns on either side of and against said structure are formed from a gate material, the method further comprising, after freeing of the bars containing the second material, steps of:
forming an insulating encapsulation between and around the gate patterns,
partially removing said gate material so as to preserve a lower block of gate material and free cavities above this lower block of gate material and surrounded by the encapsulation,
filling the cavities with at least one insulating layer so as to form an insulation zone on the lower block of gate material, then
filling the cavities with at least one layer of gate material, so as to form an upper block of gate material on the insulation zone.

According to one possible implementation, after the formation of the gate patterns and before formation of the encapsulation, the method can further comprise:
forming an insulating spacer distributed conformally on the gate patterns and between the gate patterns and arranged on a central zone of said stack structure.

Advantageously, the method can further comprise steps of:
removing the insulating encapsulation between the gate patterns or between the gate blocks, so as to free one or more spaces,
forming exchange gates in the space(s).

### BRIEF DESCRIPTION OF THE DRAWINGS

The present invention will be better understood upon reading the description of exemplary embodiments provided merely for illustrative purposes and which are in no way limiting, with reference to the appended drawings wherein:

FIG. 1A, FIG. 18 and FIG. 28 illustrate an example of a quantum device according to the invention with several levels of superimposed semiconductor bars and respectively a first pair of superimposed gates and a second pair of superimposed gates distributed along semiconductor bars.

FIG. 2 illustrates an example of a quantum device including a superposition of the semiconductor bars and of the pairs of superimposed gates along the bars, the pairs here being insulated from each other.

FIG. 3 illustrates an exemplary embodiment of the quantum device with charge reservoirs at the ends of the bars.

FIG. 4 illustrates an example of a quantum device including a superposition of the semiconductor bars and of the pairs of superimposed gates along the bars, one or more exchange gates being provided here between each pair.

FIG. 5, FIG. 6A, FIG. 6B illustrate an exemplary embodiment of a semiconductor structure of an active zone with semiconductor bars stacked to form a quantum device.

FIGS. 7A, 7B, 8A, and 8B illustrate an exemplary embodiment of lateral removal of certain semiconductor bars of the structure to form recesses and be able to create dielectric plugs in these recesses.

FIGS. 9, 10 and 11 Illustrate an exemplary embodiment of gate patterns.

FIGS. 12, 13 and 14 illustrate an exemplary embodiment of charge reservoirs.

FIG. 15 illustrates an exemplary embodiment of an insulating encapsulation between and around the gate patterns.

FIGS. 16 and 17 illustrate an example of selective removal of bars containing a first material to free semiconductor bars intended to each receive typically one row of quantum dots.

FIGS. 18 and 19 Illustrate an exemplary embodiment of a dielectric region between the gate patterns and around the semiconductor bars.

FIGS. 20 to 23 illustrate a specific exemplary embodiment of gates superimposed according to a method with a replacement gate.

FIG. 24 is used to illustrate insulating regions in a space between neighbouring or adjacent gates.

FIGS. 25, 26 and 27 illustrate an alternative embodiment with the implementation of exchange gates in an inter-gate space.

Identical, similar or equivalent parts of the different figures bear the same reference numerals so as to make it easier to switch from one figure to another.

The different parts represented in the figures are not necessarily drawn to a uniform scale, to make the figures more legible.

In addition, in the following description, terms which depend on the orientation of the structure such as “above”, “below”, “lower”, “upper”, “juxtaposed”, “superimposed” apply on the assumption that the structure is oriented as illustrated in the figures.

### DETAILED DISCLOSURE OF SPECIFIC EMBODIMENTS

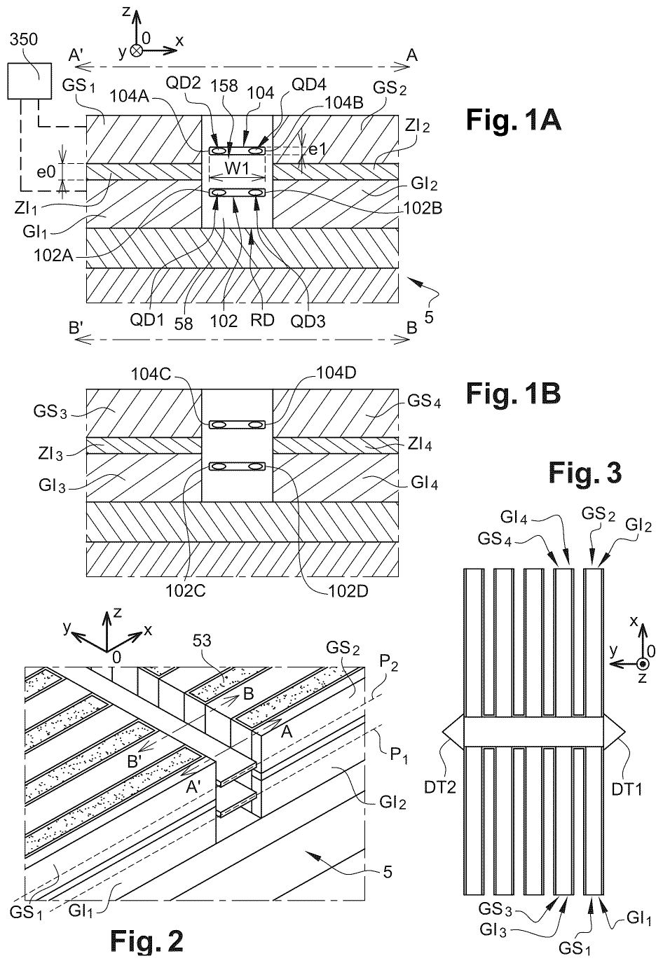

Reference is made first of all to FIGS. 1A, 1B, 2, 3 which give an exemplary embodiment of a quantum device (respectively illustrated according to a first view in a transverse cross-section A′A, according to a second view in a transverse cross-section B′B, according to a partial perspective view, and according to a top view).

The device is arranged on a substrate 5 which can be in particular of the semiconductor on insulator type, for example of the SOI (for Silicon On Insulator) or SiGeOI (for Silicon Germanium On Insulator) type or of the bulk type, for example made of silicon.

The device includes here quantum dots QD1, QD2, QD3, QD4 formed in semiconductor regions of superimposed semiconductor bars 102, 104 and for example made of silicon, in particular Si²⁸, or made of germanium. “Bar” means a layer or a strip comprising at least one semiconductor material.

“Superimposed” means that the bars are disposed one above the other, an “upper” semiconductor bar 104 of the set being disposed here above a “lower” semiconductor bar 102 without being in contact with the latter.

The semiconductor bars 102, 104 have a shape that can be advantageously parallelepipedic or substantially parallelepipedic, and extend mainly in a direction called “first direction” that is parallel to the main plane of the substrate 5 (i.e. a plane defined throughout the description as a plane passing through the substrate 5 and which is parallel to the plane [0;x;y] of an orthogonal coordinate system [0;x;y;*z]).

In the specific exemplary embodiment illustrated, the semiconductor bars 102, 104 have a width W1 greater than their thickness e1 in particular so as to confer onto them a flat appearance or that of a strip.

The semiconductor bars 102, 104 can thus be provided with a width W1 (i.e. dimension measured parallel to the axis x of the orthogonal coordinate system [0;x;y;ºz] given in FIG. 1A) comprised for example between 20 nm and 100 nm, advantageously between 40 nm and 80 nm. As for the thickness e1 (i.e. dimension measured parallel to the axis z of the orthogonal coordinate system [0;x;y;ºz]) of the semiconductor bars 102A, 102B, it can be between for example 5 nm and 20, advantageously between 10 nm and 15 nm.

As visible in FIGS. 1A, 1B, the bars 102, 104 are typically surrounded by at least one dielectric material 58, for example chosen from one of the following materials: SiO₂, SiN, HfO₂. An insulating zone 158 is thus provided between the bars 102, 104 in order to preferably prevent an electrostatic coupling between bars 102, 104.

The quantum device is also provided with various superimposed gates GI1, GS1, GI2, GS2, GI3, GS3, GI4, GS4 having an oblong shape, advantageously parallelepipedic or substantially parallelepipedic, and which extend mainly in a second direction that is parallel to the main plane of the substrate 5 and orthogonal to the first direction. Each gate GI1, GS1, GI2, GS2 can be formed by a conductive or semiconductor block made of gate material 22, for example polysilicon, against a gate dielectric layer disposed between the gate block and the semiconductor bars. According to one possible implementation, this gate dielectric layer can contain the same dielectric material 58 as that of the insulating zone 158.

In this exemplary embodiment, there is advantageously an alignment of lower gates GI1, GI2, GI3, G14 and of the lower semiconductor block 102 in the same plane P1 and an alignment of the upper gates GS1, GS2, GS3, GS4 and of the upper semiconductor block 104 in the same upper plane P2 distinct from the plane P1, the planes P1 and P2 being typically planes parallel or substantially parallel to the main plane of the substrate 5.

The operation of the device is based on a capacitive coupling between each quantum device QD1 (respectively QD2, QD3, QD4) and an associated control gate GI1 (respectively GS1, GI2, GS2) arranged opposite or facing this dot. In this example, because of a sufficient width W1 of each of the semiconductor bars 102, 104, typically with W1 greater than 40 nm, each bar 102 (resp. 104) can, in a cross-sectional view (the cross-section being in a direction orthogonal to that of the bars 102, 104 and typically parallel to that of gates (in other words a direction parallel to the axis x)), be intended to receive two quantum dots QD1, QD3 (resp. QD2, QD4). According to an alternative embodiment, each bar 102, 104 is intended to receive, in a cross-sectional view, a single quantum dot. In this case, the width W1 of each of the semiconductor bars 102, 104 is typically 20 nm. In general, the width W1 of each of the semiconductor bars 102, 104 is adapted according to the desired number of quantum dots.

A first group of superimposed gates GI1, GS1 with a first “lower” gate GI1 is provided for the control respectively of a first semiconductor region 102A of the lower semiconductor bar 102 in which the quantum dot QD1 is formed while a first “upper” gate GS1 is provided for the control of the first upper semiconductor region 104A of the upper semiconductor bar 104 and in which the quantum QD2 is formed. The gate GI1 controls, according to an electrostatic potential that is applied to it, the chemical potential of the first quantum dot QD1, while the gate GS1, Independent of the gate GI1, controls according to an electrostatic potential that is applied to it the chemical potential of the second quantum dot QD2.

The first upper gate GS1 is superimposed on and separated from the first lower gate GI1 via a first insulation zone ZI1. This first zone ZI1 for insulating the lower GI1 and upper GS1 gates from each other is typically made of an insulating material and preferably has a thickness e₀ sufficient to electrically insulate the gates GI1, GS1 from one another. For example, the first insulation zone ZI1 is formed from SiO₂ and has a thickness e₀ that can be between for example 5 nm and 20 nm. In the example illustrated, the first insulation zone ZI1 is in contact with the lower gate GI1 and the upper gate GS1 and extends from the lower gate GI1 to the upper gate GS1 so that the thickness e, of the first insulation zone ZI1 corresponds to a distance separating the lower gate GI1 and the upper gate GS1 measured in a direction orthogonal to a main plane of the substrate 5.

To allow to carry out a control of the quantum dots QD3, QD4, a second group of gates GI2, GS2 is typically provided.

A gate GI2 of the second group can thus be provided opposite a second semiconductor region 102B of the lower semiconductor bar 102 in which the quantum device QD3 is formed while a gate GS2 independent of the gate GI2 can be disposed opposite a semiconductor region 104B of the upper semiconductor bar 104 and in which the quantum dot QD4 is formed. The gate GI2 controls, according to an electrostatic potential that is applied to it, the chemical potential of the third quantum dot QD3, while the gate GS2 controls, according to an electrostatic potential that is applied to it, the chemical potential of the fourth quantum dot QD4. A second insulation zone ZI2, for example also containing SiO₂and having a thickness e₀, is also provided between the lower GI2 and upper GS2 gates of the second group.

In the exemplary embodiment illustrated in FIG. 1A, a dielectric region RD is arranged between the first group of gates GI1, GS1 and the second group of gates GI2, GS2 and encapsulates the set of superimposed semiconductor bars 102, 104.

As visible in FIGS. 1B, 2 and 3, another lower gate GI3 can be provided to control another quantum dot of the same lower row as the first quantum dot QD1 and formed in the lower bar 102, while another upper gate GS3 can be provided to control a quantum dot of the same upper row as the second quantum dot QD2 and formed in the upper bar 104. The lower gate GI3 and the upper gate GS3 are thus disposed opposite respectively a lower semiconductor region 102C of the lower semiconductor bar 102 and an upper semiconductor region 104C of the upper semiconductor bar 104. The lower gate GI3 is here also separated from the upper gate GS3 superimposed on and separated from the third lower gate by an insulation zone ZI3.

A lower gate GI4 can be provided to control a quantum dot of the same lower row as the third quantum dot QD3, while another upper gate GS4 can be provided to control a quantum dot of the same upper row as the fourth quantum dot QD4. Thus, a group of superimposed gates GI4, GS4 comprises a lower gate GI4 and an upper gate GS4 superimposed on and separated from the fourth lower gate by an insulation zone ZI4. The lower gate GI4 and the upper gate GS4 are disposed opposite respectively a lower semiconductor region 102D of the lower semiconductor bar 102 and a fourth upper semiconductor region 104D of the upper semiconductor bar 104.

Thus, the quantum device is here advantageously provided with a plurality of lower gates GI1, GI3 on a first side of the lower semiconductor bar 102 to control a first row of quantum dots. The device can also be provided with a plurality of lower gates GI2, GI4 disposed on a side opposite to the first side of the lower semiconductor bar 102 to control a second row of quantum dots opposite to the first row.

Likewise, the device can be provided with a plurality of upper gates GS1, GS3 on a first side of the upper semiconductor bar 104 to control a third row of quantum dots as well as a plurality of upper gates GS2, GS4 disposed on a side opposite to the first side of the upper semiconductor bar 104 to control a fourth row of quantum dots opposite to the third row.

The quantum dots QD1, QD2, QD3, QD4 each ensure the confinement of at least one elementary charge (electron(s) or hole(s)). Preferably, each quantum dot QD1, QD2, QD3, QD4 includes here a single elementary charge. The spin of this charge, in particular an electron, allows to encode the quantum information. In this case, the qubits associated with the quantum dots QD1, QD2, QD3, QD4 are spin qubits.

To allow to detect a quantum state also called “charge state” of the quantum dots QD1, QD2, QD3, QD4, a device for detection by reflectometry can in particular be provided.

The state of a quantum dot QD1 (resp. QD2, QD3, QD4) can be read by coupling a reflectometry circuit 350 to the gate GI1 (resp. GS2, GI2, GS2) located in its immediate vicinity and opposite or facing this quantum dot QD1.

The detection of the charge state of a quantum dot QD1 can here be implemented by applying an RF signal SE onto the gate GI1 and by receiving a reflected RF signal S_{R} consecutive to the emission of the RF signal S_{E}. The RF signal S_{E} is typically a high-frequency signal (for example between 100 MHz and 1 GHz) sent over the region 104A. The RF signal reflected by this region 104A is then demodulated by the reflectometry circuit 350. An inductance 352 is used to create a resonator LC composed of this inductance 352 and which depends on a quantum capacity Cq formed by the quantum dot BQ1 and the gate GI1. When the value of Cq varies, the phase and the amplitude of the reflected signal vary, which can be detected by the measurement means. It is thus possible to know the relative charge state of the quantum dot QD1 of the qubit intended to be read.

In the specific exemplary embodiment illustrated in FIG. 2, the inter-gate spaces are filled with an insulating material 53. Thus, the gate GI1 is insulated here from the gate GI3 that controls a quantum dot of the same row of quantum dots as the gate GI1. Likewise, the adjacent upper gates GS1 and GS3 are insulated here from one another, via a zone of insulating material 53, for example SiO₂.

As visible in the top view of FIG. 3, the device can also be provided with charge reservoirs, in particular with doped regions DT1 and DT2 at the ends of the lower and upper bars 102, 104. These doped regions DT1, DT2 can be in the form of blocks, typically made of doped semiconductor material, for example silicon doped with phosphorus or silicon germanium doped with boron. In the specific exemplary embodiment illustrated, each block forming a doped region DT1, DT2 is connected to an end of all of the semiconductor bars 102, 104 (the bars not being visible in FIG. 3).

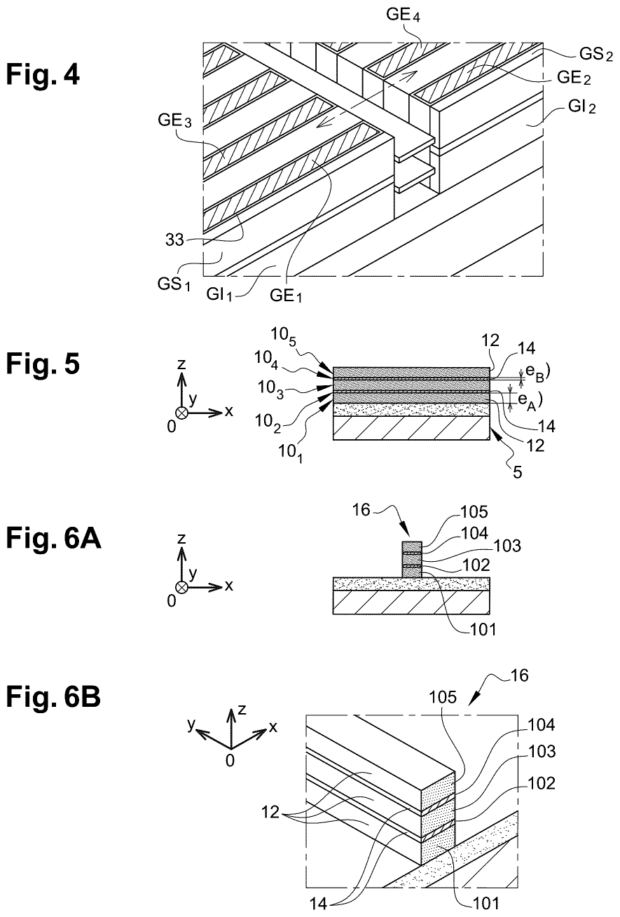

According to an alternative of the exemplary embodiment illustrated in FIG. 2 exchange electrodes GE1, GE2, GE3, GE4 also called “exchange gates” can be provided in inter-gate spaces. In the specific exemplary embodiment of FIG. 4, a single exchange electrode in the same inter-gate space.

The exchange electrodes GE1, GE2, GE3, GE4 extend mainly in a direction parallel to that in which the gates GI1, GS1, GI3, GS3 extend and which is preferably orthogonal to the first direction in other words to the direction in which the semiconductor bars 102, 104 for receiving the quantum dots extend. Each exchange electrode is typically separated from the adjacent gates via an insulating spacer layer 33.

The exchange electrodes allow to carry out exchanges of charges between neighbouring quantum dots, or between neighbouring detection islands, distributed along the same semiconductor bar. Thus an exchange electrode can allow an exchange of charges between a first lower semiconductor region 102A controlled by a gate GI1 and another lower semiconductor region 102C controlled by a gate GI3 adjacent to the gate GI1 and located in the same semiconductor bar 102 as the first lower semiconductor region 102A.

An arrangement of exchange electrodes similar to that of the gates GS3, GI3 or GS1, GI1 can be provided so that an upper exchange electrode is disposed above a lower exchange electrode and insulated from this lower exchange electrode by the insulating layer an insulating separation layer.

The implementation of exchange electrodes is optional, in particular when the pitch Δ of distribution of the gates is small and for example less than 40 nm. In this case, it is some of the gates that can be used to control the exchange between adjacent quantum dots or detection islands of the same semiconductor bar.

A specific arrangement of the dielectric region RD for encapsulation of the bars is given in FIG. 28 (which reproduces the same structure as FIG. 1A but without the reflectometry device 350).

In a first plane Po1 orthogonal to a main plane of the substrate and passing between the first group of gates GI1, GS1 and the set of superimposed semiconductor bars 102, 104, a first dielectric portion 281 of the dielectric region RD only consists of dielectric material. This first dielectric portion 281 extends against and in contact with a lateral face FLGS1 of the first upper gate GS1 and against and in contact with a lateral face of the first lower gate FLGI1. The first dielectric portion 281 includes a lower end 2811 located in the extension of a lower face FlGI1 of the first lower gate GI1 and an upper end 281s located in the extension of an upper face FSGS1 of the first upper gate GS1. In a second plane Po2 orthogonal to a main plane of the substrate and passing between the second group of gates GI2, GS2 and the set of superimposed semiconductor bars 102, 104, a second dielectric portion 282 of the dielectric region RD only consists of dielectric material. This second dielectric portion 282 extends against and in contact with a lateral face FLGS2 of the second upper gate GS2 and against and in contact with a lateral face of the second lower gate FLGI2. The second dielectric portion 282 includes a lower end 282i located in the extension of a lower face FlGI2 of the second lower gate GI2 and an upper end 282s located in the extension of an upper face FSGS2 of the second upper gate GS2.

In one or the other of the exemplary embodiments that have just been given, the device comprises two levels or stages of quantum dots. However, the quantum device is not limited to this number and can integrate a higher number k (with k>2) of stages. Thus, more generally, a quantum device as implemented according to the invention can comprise a number k of stages of superimposed semiconductor blocks greater than two, with k for example between 3 and 10.

Alternatively to one or the other of the examples described above, it is possible to provide a single row of quantum dots per semiconductor bar 102, 104.

In this case, the superimposed semiconductor bars 102, 104 are provided with a smaller width W1, and in particular a higher ratio e1/W1 of its thickness over its width. It is however possible to preserve one or more pairs of gates GI1, GI2 (resp. GS1, GS2) on either side of each bar 102, 104. In this case, the gates GI1, GI2 disposed respectively facing a region 102A located on a lateral portion of the bar 102 and facing another region 102B located on an opposite lateral portion of the bar 102 are associated with the same quantum dot. The gates GI1, GI2 can be in particular connected to one another and provided to control the chemical potential of the same quantum dot. Alternatively, the gates GI1, GI2 for lateral control of the same lower bar can be independent and thus disconnected from one another, one gate being provided to control the chemical potential of the quantum dot, the other being dedicated to measuring and transmitting the RF reflectometry signal. Likewise, the gates GS1, GS2 for lateral control of the same upper bar can be electrically independent, which means that they can be set to different potentials.

In one or the other of the examples of quantum devices described above, the superposition of bars is preferably only controlled laterally by the groups of gates GI1, GI2, GS1, GS2, GI3, GS3, GI4, GS4. Preferably, there is no control electrode located above the bars or between the latter. Thus, in a plane orthogonal to the substrate 5 and passing through the bars 102, 105, no additional electrode for controlling the bars is preferably provided in order to avoid a phenomenon of untimely screening.

A quantum device as provided according to one or more of the previously described modes can be implemented using a thin-film microelectronic manufacturing method.

Reference is made first of all to FIG. 5 which gives an example of a possible starting structure for creating a quantum device according to the invention and which includes here a substrate 5, wherein this substrate 5 can be of the semiconductor on insulator, for example SOI, type or of the bulk type and for example made of silicon.

A stack of layers formed by an alternation of layers 10₁, 10₃, 10₅ made of a first material 12 and layers 102, 104 made of a second semiconductor material 14 is first of all formed on the substrate 5.

The materials 12, 14 are typically semiconductor materials different from one another, the first material 12 being capable of being etched selectively with respect to the second material 14. The stack is in this case typically made by successive epitaxies. The specific exemplary embodiment illustrated in FIG. 5 provides an odd number of layers, in particular five layers, but the method can be carried out with a different and in particular greater number of layers.

The layers 10₁, 10₃, 10₅ containing the first material 12 can be advantageously made with a thickness e_{A} greater than that of the layers 10₂, 10₄ containing the second material 14 and which can be for example more than two times greater than that of the layers 10₂, 10₄. The layers 10₁, 10₃, 10₅ containing the first material 12 can have a thickness e_{A} for example between 10 nm and 50 nm, while the layers 10₂, 10₄ have a thickness e_{B} for example between 5 nm and 20 nm. For example, the first material 12 is made of silicon, in particular Si²⁸, while the second material 14 is made of Si₁₋ₓGeₓ, with x>0, x being for example approximately 30%. The layers 10₁, 10₃, 10₅, 10₂, 10₄ can be made by successive epitaxies.

When the first layer 10₁ is made of SiGe, this layer can optionally be formed from a surface layer of silicon of an SOI substrate by a method for enrichment with germanium known to a person skilled in the art and which involves carrying out an epitaxy of silicon then carrying out an oxidation in order to make the germanium diffuse. An etching is then carried out so as to remove the oxide formed. The layer 10₁ can be alternatively the surface layer of an SiGeOI substrate.

Then (FIGS. 6A and 6B), by etching of the stack of layers, an active zone structure 16 is defined, here in the form of a block, typically having an oblong shape, for example parallelepipedic, and which extends mainly in a first direction (direction orthogonal to the plane of FIG. 6A and parallel to the axis y of the orthogonal coordinate system [0;x;y;ºz]). This can be carried out by photolithography and etching of the stack. A dry etching using fluorocarbon chemistry and carried out through while a part of the stack is protected by a lithography mask (not shown) can be carried out for this.

The structure 16 made by etching from the layers 10₁, 10₂, 10₃, 10₄, 10₅ is formed by a stack of semiconductor bars including an alternation of bars 101, 103, 105 containing the first material 12 and bars 102, 104 containing the second material 14.

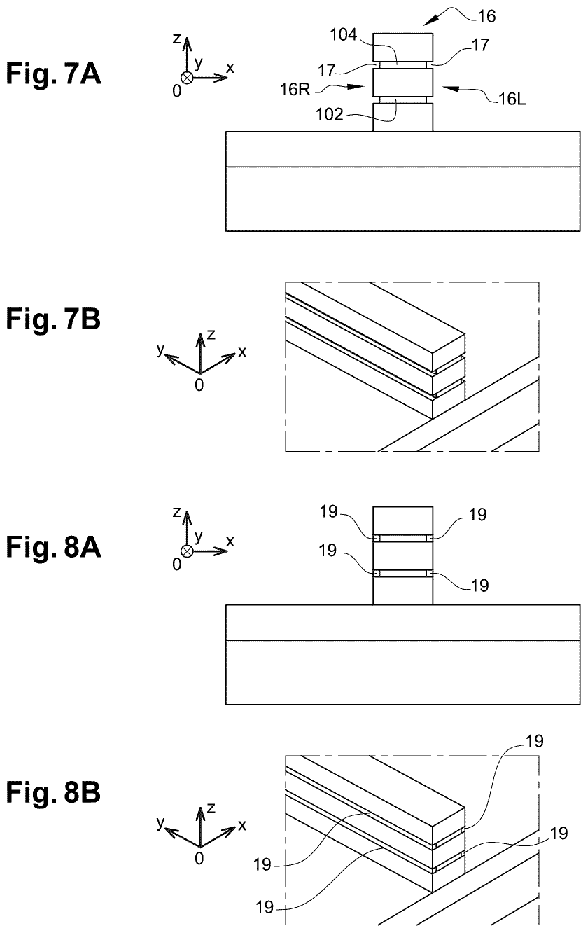

A partial etching of the bars 102, 104 containing the second material 14 is then carried out by selective etching with respect to the first material 12 so as to form lateral recesses 17 on either side of lateral sides 16L, 16R of the stack structure 16 (FIGS. 7A and 7B). This lateral etching can be carried out by wet chemical etching, for example using a solution of NH4OH, or of TMAH (tetramethylammonium hydroxide) or of TEAH (tetraethylammonium hydroxide), when Si is etched selectively with respect to SiGe. A removal of lateral portions of the bars 102, 104, for example of at least 5 nm, can be in particular when the latter have a width typically between 40 nm and 80 nm.

Then, dielectric plugs 19 are formed in the lateral recesses 17 (FIGS. 8A and 8B). For this, a deposition on the stack structure 16, advantageously conformal of dielectric material for example SIN, SiO₂ or HfO₂, according to a thickness chosen so as to fill the recesses 17, is typically carried out.

This deposition is followed by at least one etching, typically a dry etching or a combination of dry etching and wet etching of the dielectric deposited previously, so as to remove this dielectric material and only keep it in the form of the dielectric plugs 19 against and masking the lateral sides of the blocks 102, 104 containing the second material 14.

Gate patterns 25 made of gate material 22 are then formed on either side of the structure 16.

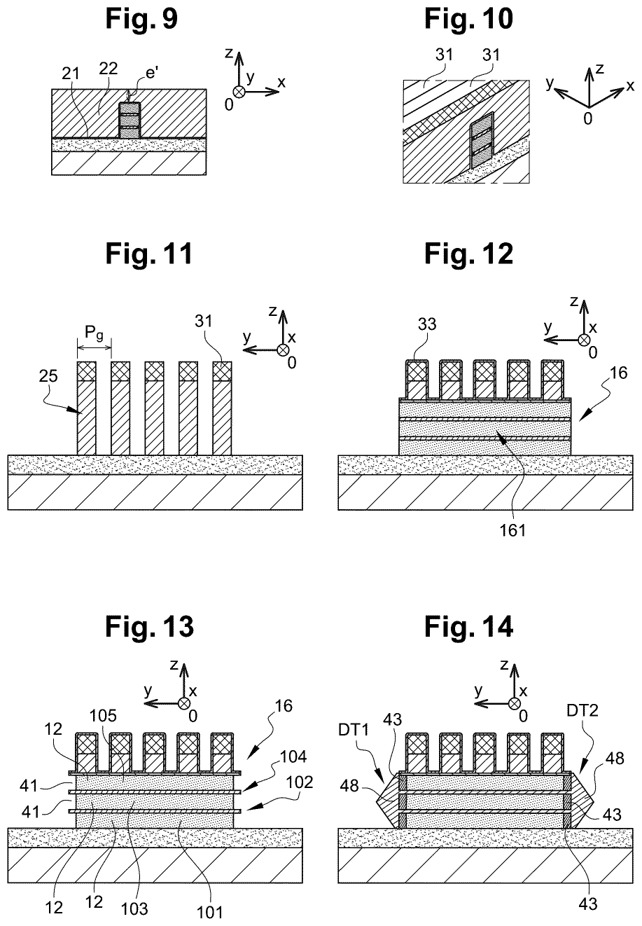

For this, at least one layer 21 of gate dielectric, for example of silicon oxide (SiO₂) or formed by a stack of silicon oxide and of a high-k material for example such as HfO₂, can first of all be deposited. This deposition is followed by that of at least one layer of conductive gate material 22 such as doped polysilicon (FIG. 9).

Preferably, after deposition and an optional planarisation by CMP (chemical mechanical polishing), a non-zero thickness e′ for example of approximately 50 nm of conductive material 22 is left to protrude above the active zone structure 16.

Hard masks 31, typically dielectric and for example formed by a stack of SiN and of SiO₂, are then carried out (FIG. 10).

Then (FIG. 11 giving a cross-sectional view according to a first cutting plane parallel to the coordinate system [0;y;ºz]) a lithography and an etching of the gate stack is carried out to form a network of parallel gate patterns 25 having an elongated shape. The patterns 25 can be for example in the form of parallelepipedic blocks, and typically extend orthogonally to the bars of the structure 16.

The gate patterns 25 can be distributed according to a low pitch Pg, for example approximately 100 nm, or even less, for example 40 nm, to form a dense network of patterns 25.

After the formation of the gate patterns 25, reservoirs of dopants DT1, DT2 (FIGS. 12 to 14) can advantageously be formed.

According to one method, first of all a thin insulating layer of spacer 33 is conformally deposited on the gate patterns 25, for example made silicon nitride and having a thickness that can be between for example 5 nm and 10 nm. The thin insulating layer of spacer 33 is arranged on and between the gate patterns 25, for example by a technique of the ALD (for Atomic Layer Deposition) type in order to fill the spaces between gate patterns without creating a filling defect.

Then a lithography is carried out so as to remove portions of the thin insulating layer of spacer 33 and extend this etching into parts of the active zone structure 16 located around another part 161 vertically in line with all of the gate patterns 25 (FIG. 12 giving a cross-sectional view according to a cutting plane parallel to the coordinate system [0;x;y;ºz]). To carry out this removal, an example of a method comprises the formation of a lithographic stack, for example a tri-layer formed from a layer of SOC, an anti-reflective layer, a photosensitive resin, which is deposited then insulated. The lithography stack protects the zones in which the dielectric of the thin insulating layer of spacer 33 must be preserved. Dry etching of the fluorocarbon type can be provided to remove the thin insulating layer of spacer 33 containing SiN outside of the protected zones.

To form the reservoirs of dopants in contact with the ends of the semiconductor bars 102, 104 without placing these reservoirs in contact with the other bars 101, 103, 105 of the structure, it is advantageously possible to carry out a partial selective etching of the first material 12 with respect to the second material 14 in order to remove portions of ends of the bars 102, 104 and create hollows 41 (FIG. 13) at ends of the structure 16.

For example, when the first material 12 is made of SiGe, this etching is carried out for example by wet chemical etching, or using HCl or an HF:H202:CH3COOH mixture. It is advantageously possible to provide a ratio close to or equal to 1:1 between the depth etched and the thickness of the etched layer. A removal for example of at least 5 nm can be provided to create these hollows 41. The hollows 41 are then filled with insulating plugs 43 also called “internal spacers”. This can be carried out for example via conformal deposition of a dielectric material, for example SiN or SiO₂. This deposition is typically followed by dry etching or by a combination of dry and wet etching of the dielectric deposited, so as to form insulating plugs 43 blocking the access to the bars 101, 103, 105 containing the first material 12.

Once the insulating pugs 43 have been created, a selective epitaxy (FIG. 14) of semiconductor material 48 can be carried out starting from the exposed ends of the bars 102, 104 containing the second material 14. The epitaxy can provide in situ doping. For example reservoirs of dopants DT1, DT2 made of Si:P or made of SiGe:B can be formed by epitaxy starting from ends of the bars 102, 104 made of silicon. The epitaxy formed can follow preferred crystalline orientations or not, and the epitaxy fronts coming from the various layers of Si can optionally join together like in the exemplary embodiment shown in FIG. 13 to form semiconductor blocks or clusters.

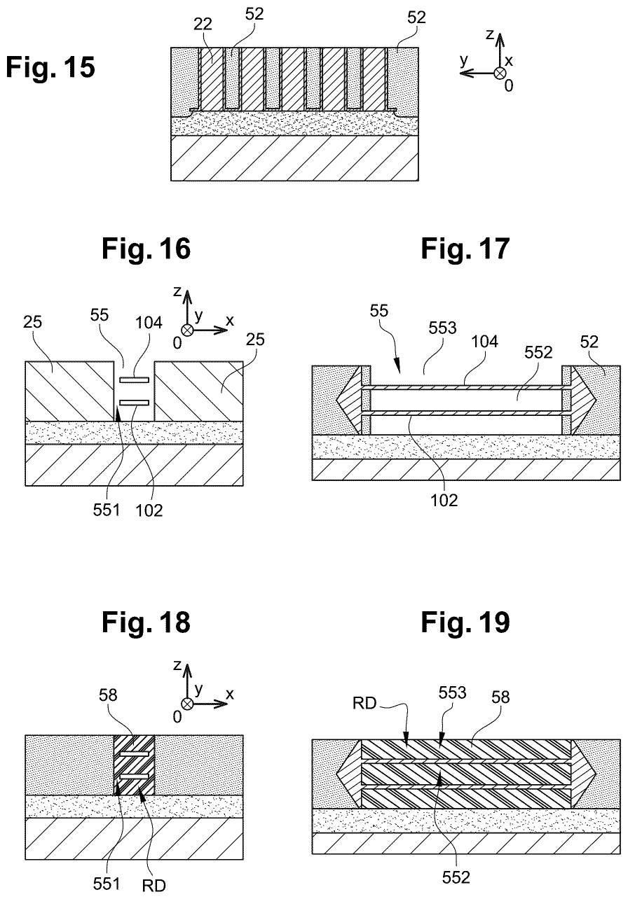

An insulating encapsulation 52 is then carried out around the gate patterns. The insulating encapsulation 52 can be carried out for example by deposition of a material of the PMD (for Pre-Metal Dielectric) type for example such as SiO₂ on the entire structure 16 followed by a step of CMP planarisation. This step is carried out preferably so that the polishing front stops at the top of the active zone structure 16. This allows to expose the material 22 of the gate patterns, typically made of conductive gate material such as polysilicon (FIG. 15),

The final structure intended to house the quantum dots is provided here in the form of suspended and superimposed semiconductor bars 102, 104, the bars 102, 104 being spaced apart from one another.

For this, a freeing (FIGS. 16 and 17) in this structure of the semiconductor bars 102, 104 containing the second material 14 is then carried out by removing the bars containing the first material 12 by selective etching with respect to the second material 14. Such a step is shown in FIGS. 16 and 17. This freeing is typically accompanied by the removal of the dielectric plugs 19 arranged along the bars containing the second material 14. This freeing is advantageously implemented using several substeps of etching, in particular of selective wet etching.

Typically, a method is implemented in which first of all a removal layer by layer from the top of the structure 16 is carried out. The upper layer 105 of first semiconductor material 12 is thus etched, then the sacrificial plugs 19 on either side of the layer 104 of second material 14, then the layer 103 of first semiconductor material 12, then the plugs 19 on either side of the layer 102 of second material 14, then the upper layer 101 of first semiconductor material 12.

A selective etching of the SiGe with respect to the Si can for example be carried out using HCl or a HF:H2O2:CH3COOH mixture. As many sequences of etchings as stages of bars containing the first material 12 can be provided.

The freeing of the bars 102, 104 containing the second material leads to the formation of a space 55, in other words of a cavity, that extends around and between the bars 102, 104 and is located between the gate patterns 25.

Then (FIGS. 18 and 19), a filling of this space 55 using at least one dielectric material 58 for example such as SiO₂, or SiN, or HfO₂ is carried out in order to form a dielectric region RD coating the bars 102, 104.

Typically, a conformal deposition of the dielectric material 58 then a step of planarisation for example by CMP is carried out for this.

In the case in which the dielectric plugs 19 have been previously partially removed or etched during the step of freeing the semiconductor bars 102, 104 described above, the dielectric material 58 acts as a gate dielectric or forms a thickness of gate dielectric in locations 551 located between the semiconductor bars 102, 104 and the gate patterns 25. A volume 552 separating the semiconductor bars 102, 104 and a zone 553 around all of the bars 102, 104 is also filled.

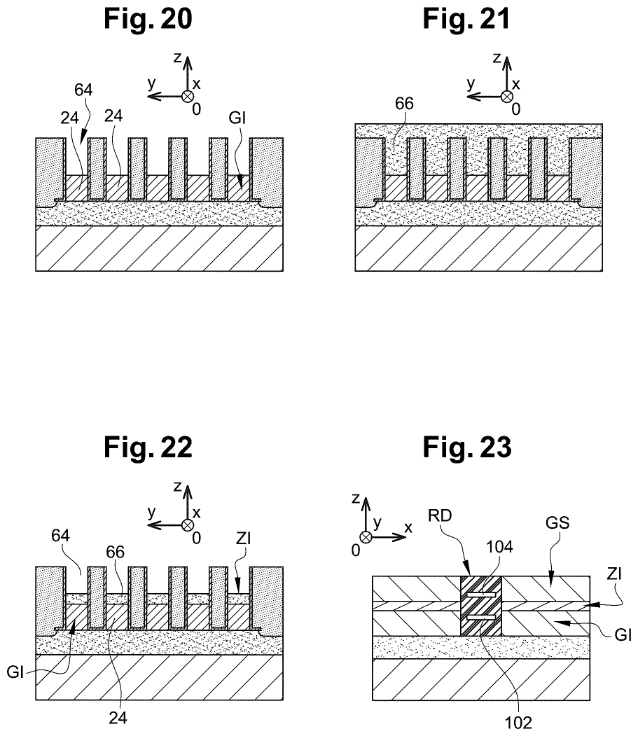

The formation of superimposed gates is then completed. For this, a partial etching of the material 22 of the gate patterns (FIG. 20) is carried out. The partial removal of the gate material 22 is carried out so as to preserve a lower block 24 of gate material and create cavities 64 surrounded by the encapsulation 52 and disposed above this lower block 24 of gate material. Dry etching or chemical etching, in particular wet etching using TMAH, is in particular implemented when the material 22 is polySi.

The etching is carried out so as to control the height of the lower block 24 of gate material with respect to that of the semiconductor layers of the active zone structure 16. A partial removal is implemented so that this block 24 intended to form lower gates GI is opposite only the lower semiconductor bar 102.

These cavities 64 are then filled (FIG. 21) with at least one layer of insulating material 66, for example SiO₂. This deposition is optionally followed by a planarisation and an etching (FIG. 22) to partially remove the insulating material 66 deposited. The insulating material 66 is used to form an insulation zone ZI allowing to insulate the lower-stage gates GI from the upper-stage gates GS. A new layer of conductive material, advantageously containing the same conductive material 22 as the lower gate GI, for example polysilicon, is then deposited so as to fill the cavities 64. A planarisation by CMP is then typically carried out to thus form upper gates GS opposite the upper bar 104 (FIG. 23).

In the example of a creation method that has just been given, for the implementation of the superimposed gates GI, GS, lower gates GI formed from the same material 22 as the upper gates GS are provided. Alternatively, it is however possible to provide different materials between the lower gates GI on the one hand and the upper gates GS on the other hand.

Likewise, in the exemplary embodiment that has just been given, the gates formed against the portion 16R of active zone dedicated for example to housing the quantum dots contain the same material as those located against the portion 16L of active zone that faces it and which is dedicated for example to housing the detection islands.

Alternatively, it is however possible to provide different materials between on the one hand the gates located against the portion 16R and on the other hand the gates located against the portion 16L. Such an alternative can be carried out to obtain work functions and consequently operating modes that are different between for example gates controlling the quantum dots and gates controlling the detection islands. To carry out such an alternative, it is possible to add one or more additional lithography steps and one or more additional deposition steps.

As an alternative to the example of a creation method that has just been given for the implementation of the superimposed gates GI, GS, which describes an approach of the type commonly called “gate-last” (with a replacement gate) in which an at least partial replacement of gate patterns by a stack with gates separated by an insulation zone is carried out, it is possible to directly create gate patterns composed of this stack.

Thus, according to this alternative embodiment of the gates, an approach of the type called “gate-first” can be provided. In this case, directly after the step of forming the active zone structure 16 described previously in connection with FIGS. 6A-6B, provision can be made for making a stack of layers to form the lower gate, the insulation zone, and then the upper gate. The thicknesses of the conductive or semiconductor layers of gate material(s) and of the interposed insulating layer are then preferably adjusted according to those of the layers of first material 12 and of second material 14 of the structure 16 so that each layer of gate material is disposed opposite and in the same plane parallel to the main plane of the substrate as a layer containing the second semiconductor material 14 and in which quantum dots or detection islands are provided.

In either of the exemplary embodiments that have just been described, the contact on different levels of gates as well as on different levels of semiconductor layers can be carried out for example by providing, at the ends of the gate structures or portions of active zone, a staircase shape.

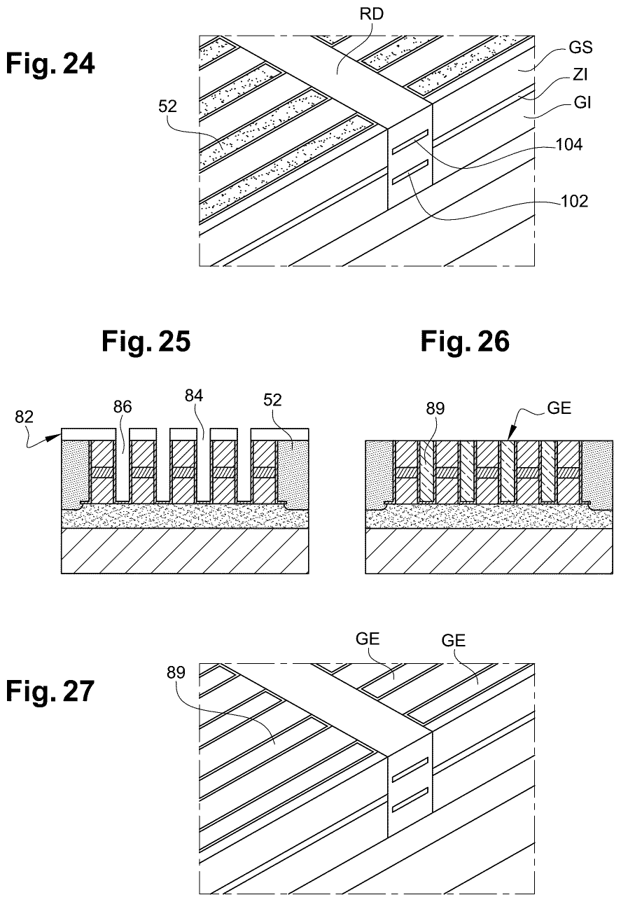

In the exemplary embodiment illustrated in FIG. 24, the “inter-gate” space(s) between neighbouring or adjacent gates distributed along bars 102, 104 are filled with insulating material, here with the encapsulation 52.

Alternatively, it is possible to create exchange electrodes in the inter-gate space(s).

For this, a method illustrated in FIGS. 25 to 27 involves starting from a structure as obtained after the creation of the gates. A masking 82, typically made of photosensitive resin, is then carried out in a zone located above the set of gate blocks and which includes openings 84 opposite inter-gate spaces (FIG. 25). The insulating encapsulation material 52, for example SiO₂, located in the inter-gate spaces is then etched selectively with respect to the thin layer of spacer 33, for example made of SiN, in order to form holes 86. A method for fluorocarbon dry etching can in particular be used.

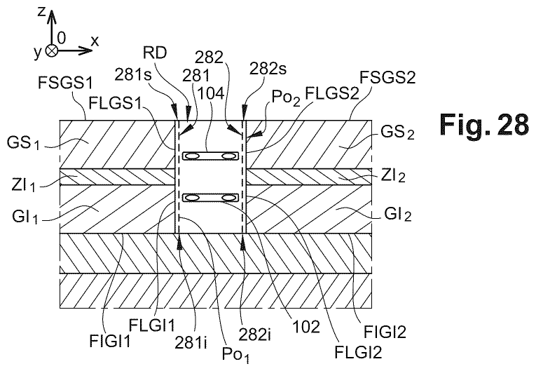

After removal of the masking 82, a deposition of conductive material 89, for example a stack of the TiN/W type, is carried out to fill the holes 414 thus defined (FIG. 26). This deposition is typically followed by a step of CMP planarisation. The stopping of the planarisation is carried out preferably when the top of the active zone structure (not visible in FIGS. 26 and 27) is reached. In this exemplary embodiment a single exchange electrode GE per inter-gate space is created.

However, it is possible in an alternative to form superimposed exchange gates that follow an arrangement similar to that of the gate electrodes between which these exchange gates are interposed. It is thus possible to form in each inter-gate space pairs of superimposed exchange gates separated from each other by an insulator. For this, it is possible to follow a method similar to that used to create the gates and described above in relation to FIGS. 11 to 20-22.

1. A quantum electronic device provided with a substrate and comprising, on the substrate:
a set of superimposed semiconductor bars comprising at least one lower semiconductor bar and at least one upper semiconductor bar, the lower semiconductor bar and the upper semiconductor bar being disposed one above the other,
a first group of superimposed gates comprising a first lower gate and a first upper gate, the first upper gate being superimposed on the first lower gate and separated from the first lower gate by an insulation zone, the first lower gate being disposed opposite a first region of the lower semiconductor bar, the first lower gate being a gate for lateral control of the lower semiconductor bar capable of being coupled via capacitive coupling to the first region, so as to form a first quantum dot in the first region of the lower semiconductor bar, the first upper gate being disposed opposite a first region of the upper semiconductor bar, the first upper gate being a gate for lateral control of the upper semiconductor bar and being capable of being coupled via capacitive coupling to the first region of the upper semiconductor bar so as to form a second quantum dot in the first region of the upper semiconductor bar,
a second group of gates comprising a second lower gate and a second upper gate, the second upper gate being superimposed on the second lower gate and separated from the second lower gate by an insulation zone, the first lower gate being a gate for lateral control of the lower semiconductor bar disposed opposite, and capable of being coupled via capacitive coupling to, a second region of the lower semiconductor bar opposite to the first region of the lower semiconductor bar, the second upper gate being a gate for lateral control of the upper semiconductor bar disposed opposite, and capable of being coupled via capacitive coupling to, a second region of the upper semiconductor bar opposite to the first region of the upper semiconductor bar, said set of semiconductor bars being disposed between the first group of gates and the second group of gates, so that in a first plane parallel to a main plane of the substrate, the lower semiconductor bar is arranged between the first lower gate and the second lower gate and in a second plane parallel to a main plane of the substrate, the upper semiconductor bar is arranged between the first upper gate and the second upper gate.

2. The quantum electronic device according to claim 1, further comprising:
a third group of superimposed gates juxtaposed with said first group of gates, the third group of gates comprising at least one third upper gate superimposed on a third lower gate, the third upper gate being separated from the third lower gate by an insulation zone, the third lower gate and the third upper gate being disposed opposite to, respectively, a third lower semiconductor region of the lower semiconductor bar and a third upper semiconductor region of the upper semiconductor bar, and
a fourth group of gates juxtaposed with said second group of gates, the fourth group of gates comprising a fourth upper gate superimposed on a fourth lower gate, the fourth upper gate being separated from the fourth lower gate by an insulation zone, the fourth lower gate and the fourth upper gate being disposed opposite respectively a fourth lower semiconductor region of the lower semiconductor bar and a fourth upper semiconductor region of the upper semiconductor bar.

3. The device according to claim 2, further comprising, between said first group of gates and said third group of gates:
at least one exchange electrode for performing exchanges of charges between neighbouring quantum dots distributed along the same semiconductor bar out of the upper semiconductor bar and the lower semiconductor bar ,
exchange electrodes superimposed and separated from one another by at least one insulating separation layer, or
a zone of at least one insulating material.

4. Device The device according claim 1, further comprising:
a doped semiconductor block, forming a first charge reservoir, the doped semiconductor block being arranged at a first end of the upper semiconductor bar and of the first lower semiconductor bar, and
another doped semiconductor block, forming a second charge reservoir, the other doped semiconductor block being arranged at a second end of the upper semiconductor bar and of the lower semiconductor bar.

5. The device according to claim 1, wherein a dielectric region is arranged between the first group of gates and the second group of gates and encapsulates the set of superimposed semiconductor bars.

6. The device according to claim 1, wherein the insulation zone separating the first upper gate and the first lower gate is in direct contact both with an upper face of the first lower gate and with a lower face of the first upper gate and only consists of dielectric material, and wherein the insulation zone separating the second upper gate and the second lower gate is in direct contact both with an upper face of the second lower gate and with a lower face of the second upper gate and only consists of dielectric material.

7. The device according to one of claim 1, wherein the lower and upper gates of said second group of gates and/or of the first group are coupled to a circuit for measurement by reflectometry, configured to:
emit an RF signal to the second lower gate or to the second upper gate; and
detect a variation in impedance consecutive to the reception of a signal reflected by said second semiconductor region of the lower semiconductor bar or by said second upper semiconductor region of the semiconductor bar consecutively to the emission of said RF signal.

8. The device according to claim 1,
wherein the lower semiconductor bar and the upper semiconductor bar have a width smaller than a predetermined width, the second lower gate and the second upper gate being configured to respectively control a chemical potential of the first quantum dot and a chemical potential of the second quantum dot, or
wherein the lower semiconductor bar and the upper semiconductor bar have a width greater than a predetermined width, the second lower gate and the second upper gate being configured to respectively control a chemical potential of a third quantum dot formed in said second region of the lower bar and the chemical potential of a fourth quantum dot formed in said second region of the upper bar.

9. The device according to one of claim 1, wherein the gates of said groups of gates are disposed against lateral zones of the bars, and
wherein in a plane orthogonal to a plane passing through said superimposed semiconductor bars and in which said superimposed semiconductor bars are contained over an entire length thereof, the device does not include an electrode for controlling the bars or a gate for controlling the bars.

10. The device according to claim 1,
the first upper gate and the second upper gate being distinct gates electrically independent of one another so that the first upper gate and the second upper gate can be set to different respective potentials, and/or
the first lower gate and the second lower gate being distinct gates electrically independent of one another so that the first lower gate and the second lower gate can be set to different respective potentials.

11. A method for manufacturing the quantum electronic device according to claim 1, the method comprising:
creating on said substrate a structure formed by a stack of semiconductor bars comprising an alternation of bars containing a first material and bars containing a second material, the second material being a semiconductor,
forming gate patterns on either side of said structure, and
selectively removing the bars containing the first material.

12. The method according to claim 11, further comprising, before the formation of the gate patterns on either side of said structure:
partially etching the bars containing the second material by selective etching with respect to the first material so as to form recesses on either side of lateral sides of said structure, and
forming dielectric plugs in said recesses.

13. The method according to claim 11, further comprising, after formation of said structure and before the selective removal of the bars containing the second material, a formation of charge reservoirs at ends of said structure, the formation of the charge reservoirs comprising:
performing a partial selective etching of the first material with respect to the second material in order to create hollows at said ends of said stack structure,
filling said hollows with an insulating material in order to form insulating plugs in said hollows, and
carrying out performing an epitaxy of semiconductor material starting from exposed ends of the bars containing the second material, while the bars containing the first material are protected by the insulating plugs.

14. The method according to claim 11, wherein the gate patterns on either side of said structure are formed from a gate material, the method further comprising, after selective removal of the bars containing the first material:
forming an insulating encapsulation between and around the gate patterns,
partially removing said gate material so as to preserve a lower block of gate material and free cavities above the lower block of gate material and surrounded by the encapsulation,
filling the cavities with at least one insulating layer so as to form an insulation zone on the lower block of gate material, and
filling the cavities with at least one layer of gate material, so as to form an upper block of gate material on the insulation zone.

15. The method according to claim 14, wherein after formation of the gate patterns and before formation of the encapsulation, the method further comprises:
forming an insulating spacer distributed conformally on the gate patterns and between the gate patterns, and arranged on a central zone of said stack structure.

16. The method according to claim 14, further comprising:
removing the insulating encapsulation between the gate patterns or between the gate blocks, so as to free one or more spaces, and
forming exchange gates in the space(s).
